(19) United States
(12) Patent Application Publication
(10) Pub. No.: US 2006/0181935 A1
(43) Pub. Date: Aug. 17, 2006

(54) Semiconductor memory devices and methods of operating the same

(76) Inventor: Sung-Ho Choi, Suwon-si (KR)

Correspondence Address: HARNESS, DICKEY & PIERCE, P.L.C., P.O. BOX 8910, RESTON, VA, 20195, US

(21) Appl. No.: 11/172,979

(22) Filed: Jul. 5, 2005

(30) Foreign Application Priority Data
Feb. 15, 2005 (KR) 10-2005-0012189

(51) Int. Cl. G11C 7/10

(52) U.S. Cl. 365/189.01

(57) ABSTRACT

A semiconductor memory device may include a plurality of independently operated memory banks each including a plurality of wordlines. At least one of the plurality of wordlines may be activated in response to a slave command and at least one of the wordlines may be activated in response to a master command. The slave command may be independent of the master command.

### PRIORITY STATEMENT

This application claims priority under 35 USC § 119 to Korean Patent Application No. 10-2005-0012189, filed on Feb. 15, 2005, in the Korean Intellectual Property Office (KIPO), the contents of which are herein incorporated by reference in its entirety.

### BACKGROUND

1. Field of the Invention

Example embodiments of the present invention relate to semiconductor memory devices and methods of operating the same.

2. Description of the Related Art

A page size of a semiconductor memory device may be determined, for example, depending on the number of columns, which may be selected for wordlines activated by the same row address. A multimedia semiconductor memory device, for example, may have a variable page size.

In a related art semiconductor memory device, a page size may depend on the number of recognized column addresses. For example, if the number of recognized column addresses is 10, 1K (i.e., 2¹⁰=1024) columns may be selected. In this example, the semiconductor memory device may have a page size of 1K (i.e., 2¹⁰ or 1024) bytes. In another example, if the number of recognized column addresses is 11, the semiconductor memory device may have a page size of 2K (i.e., 2¹¹ or 2048 bytes).

In the related art semiconductor memory device, a fixed number of wordlines may be activated regardless of a required page size. For example, in a semiconductor memory device, which may use a page size of 1K and a page size of 2K, the number of memory cells, which may be connected to wordlines activated by a same row address, may be 2K. If a semiconductor memory device operates in a 2K page size mode, 11 column addresses may be utilized to identify 2K columns.

If the semiconductor memory device operates in a 1K page size mode, 10 column addresses may be utilized to identify 1K columns and the remaining column address may be unused.

In the related art semiconductor memory device, for example, using a 1K page size, 2K memory cells may be accessed notwithstanding that the number of columns required to be activated may be 1K. Accordingly, the related art semiconductor memory device may consume unnecessary power and/or operational speed may be reduced, for example, when unnecessary 1K memory cells are selected.

### SUMMARY

Example embodiments of the present invention may provide semiconductor memory devices, components thereof, and methods for the same, which may reduce unnecessary power consumption and/or increase operational speed caused by, for example, variation in page size.

In an example embodiment of the present invention, a semiconductor memory device may include a plurality of independently operated memory banks each of which may include a plurality of wordlines at least one of which may be activated in response to a slave command and at least one of which may be activated in response to a master command. The slave command may be independent of the master command.

In example embodiments of the present invention, the semiconductor memory device may further include a row decoder adapted to activate the at least one wordline based on a slave control signal generated in response to a slave command, which may be independent of a master command.

In another example embodiments of the present invention, a method of operating a semiconductor memory device may include receiving a master command and an input address, generating a master address and a slave address corresponding to the input address and in response to the master command, activating a wordline identified by the master address, and activating a wordline identified by the slave address in response to generation of the master command and a slave command, which may be independent of the master command.

In another example embodiment of the present invention, a row decoder for use in a semiconductor memory device may be adapted to activate the at least one wordline based on a slave control signal generated, in response to a slave command, which is independent of a master command.

In another example embodiment of the present invention, a semiconductor memory device may include a memory, which may have a variable page size determined based on a master command signal and a slave command signal, which may be independent of each other.

In another example embodiment of the present invention, a method for operating a semiconductor memory device may include determining a page size of a memory within the semiconductor memory device based on a master command signal and a slave command signal, which may be independent of each other.

In example embodiments of the present invention, the semiconductor memory device may further include an address control circuit adapted to generate a master address and a slave address based on an input address and output the master address and the slave address to the row decoder. The row decoder may activate at least two wordlines based on the master address and the slave address, respectively.

In example embodiments of the present invention, the master address and the slave address may be linked to each other and each may identify at least one wordline of different memory banks.

In example embodiments of the present invention, the at least one wordline identified by the slave address may be activated after the at least one wordline identified by the master address.

In example embodiments of the present invention, the address control circuit may further include a master address generation unit adapted to generate the master address in response to the input address and output the generated master address to the row decoder, and a slave address generation unit adapted to generate the slave address in response to the input address.

In example embodiments of the present invention, the semiconductor memory device may further include four memory banks located in first to fourth quadrants, and

the memory bank identified by the master address and the memory bank identified by the slave address may be located diagonally with respect to each other.

In example embodiments of the present invention, the master address may identify wordlines of two memory banks located diagonally with respect to each other, and the slave address may identify wordlines of two memory banks located diagonally with respect to each other.

In example embodiments of the present invention, the page size may be determined based on a plurality of independently operated memory banks, for example, within the memory, each of which includes a plurality of wordlines at least one of which may be activated in response to the slave command.

### BRIEF DESCRIPTION OF THE DRAWINGS

Example embodiments of the present invention will be more clearly understood from the following detailed description of example embodiments of the present invention taken in conjunction with the accompanying drawings, in which:

FIG. 1 is a diagram showing a semiconductor memory device, according to an example embodiment of the present invention;

FIG. 2 is a diagram showing a control signal generation circuit, according to another example embodiment of the present invention;

FIG. 3 is a diagram showing an address control circuit, according to another example embodiment of the present invention;

FIG. 4 is an example timing chart for the semiconductor memory device, according to an example embodiment of the present invention;

FIG. 5 is a diagram illustrating a memory bank in which one wordline may be activated, according to an example embodiment of the present invention; and

FIGS. 6 and 7 are example diagrams showing memory banks in which multiple wordlines may be activated, according to an example embodiment of the present invention.

### DESCRIPTION OF EXAMPLE EMBODIMENTS

Reference now should be made to the drawings, in which the same reference numerals are used throughout the different drawings to designate the same or similar components.

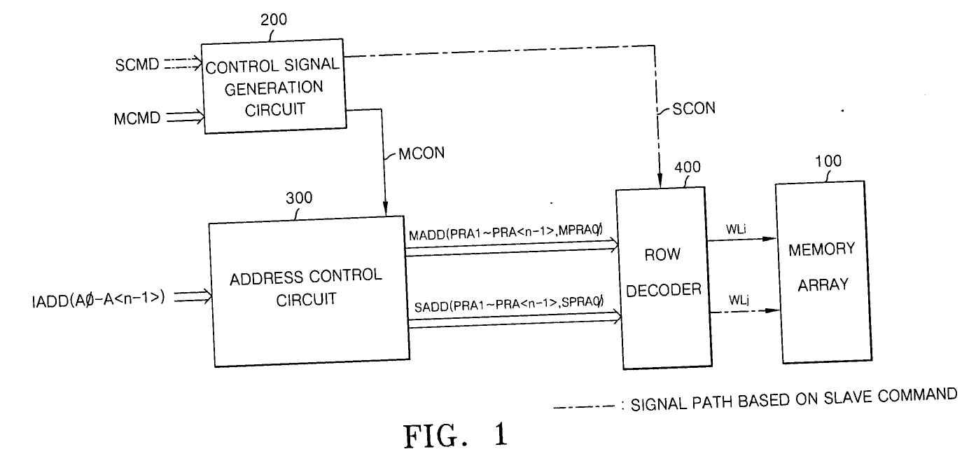

FIG. 1 is a diagram showing a semiconductor memory device, according to an example embodiment of the present invention. Referring to FIG. 1, the semiconductor memory device, according to an example embodiment of the present invention, may include a memory array 100, a control signal generation circuit 200, an address control circuit 300 and a row decoder 400.

The memory array 100 may include one or more memory banks (e.g., a plurality of memory banks), each of which may further include a plurality of wordlines. Each of the memory banks may be operated, for example, independently.

The control signal generation circuit 200 may generate a master control signal MCON, for example, in response to a master command MCMD, and a slave control SCON signal in response to a slave command signal SCMD. In example embodiments of the present invention, the slave command SCMD may be generated after, and/or independent of, the master command MCMD.

The address control circuit 300 may generate a master address MADD and a slave address SADD, corresponding to an externally provided input address IADD (AO˜A(n−1)), and/or in response to the master control signal MCON.

The master address MADD may include upper predecoding addresses PRA1˜PRA(n−1) and a master block address MPRA0. The slave address SADD may include upper predecoding addresses PRA1˜PRA(n−1) and a slave block address SPRA0. The master block address MPRA0 and the slave block address SPRA0 may correspond to a lower (e.g., the lowest) address of the master address MADD and a lower (e.g., the lowest) address of the slave address SADD, respectively.

The upper predecoding addresses PRA1˜PRA(n−1) may be utilized, for example, in generating the master address MADD and the slave address SADD. For example, the slave block address SPRA0 may be obtained by adding N to the master block address MPRA0. The slave address SADD may be linked to the master address MADD.

A wordline, which may be identified by the master address MADD, and a wordline, which may be identified by the slave address SADD, may be associated with respective memory banks, which may be different. The master block address MPRA0 and the slave block address SPRA0, which may be used to select respective memory banks, may be distinguished from each other, for example, using lowest addresses LSBs (e.g., based upon, for example, the lowest address within the respective memory banks).

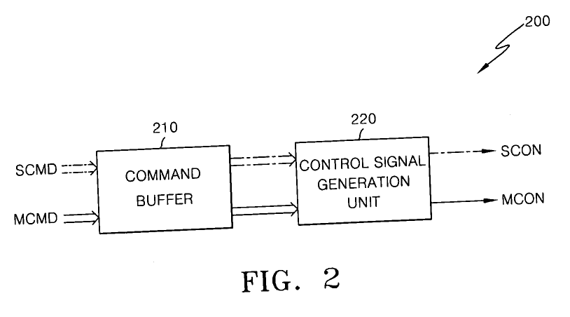

FIG. 2 is a diagram showing control signal generation circuit 200, according to an example embodiment of the present invention. In FIG. 2, a received master command MCMD and a received slave command SCMD may be buffered in a command buffer 210. A control signal generation unit 220 may generate the master control signal MCON and the slave control signal SCON, for example, in response to the buffered master command MCMD and the buffered slave command SCMD.

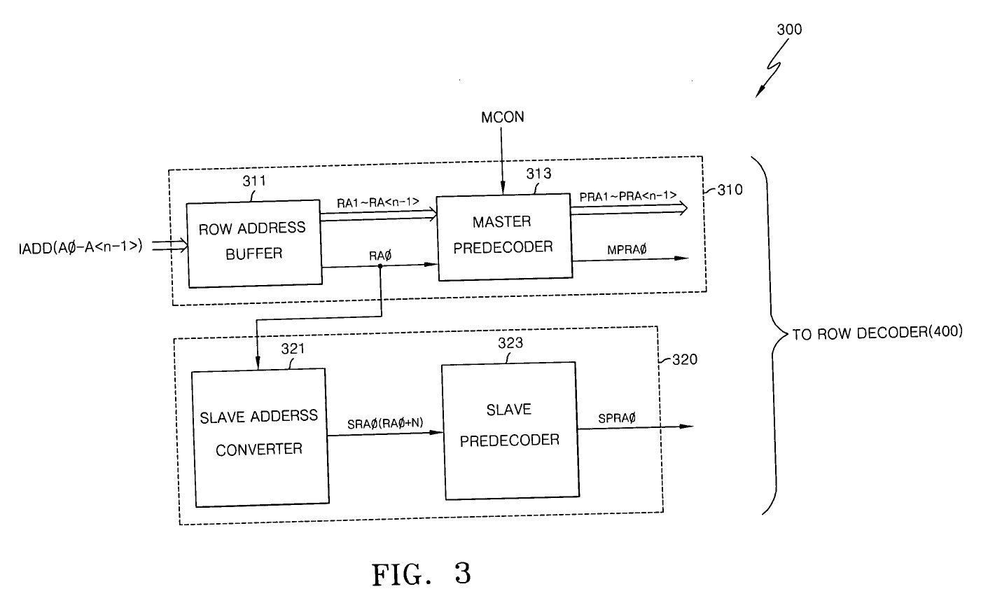

FIG. 3 is a diagram showing the address control circuit 300, according to an example embodiment of the present invention. In FIG. 3, the address control circuit 300 may include a master address generation unit 310 and a slave address generation unit 320.

The master address generation unit 310 may generate the upper predecoding addresses PRA1˜PRA(n−1) and the master block address MPRA0 in response to the input address IADD. The master address generation unit 310 may provide the upper predecoding addresses PRA1˜PRA(n−1) and the master block address MPRA0 to the row decoder 400.

The master address generation unit 310 may include a row address buffer 311 and a master predecoder 313. The row address buffer 311 may generate row addresses RA0˜RA(n−1), for example, by buffering the input address IADD. The master predecoder 313 may predecode the row addresses RA0˜RA(n−1), for example, in response to the master control signal MCON. The row addresses RA0˜RA(n−1) may be decoded as the master block address MPRA0 and the upper predecoding addresses PRA1˜PRA(n−1).

The slave address generation unit 320 may generate the slave block address SPRA0, for example, based on the buffered input address IADD(A0) (e.g., row address RA0). The slave block address SPRA0 may be provided to the row decoder 400. In example embodiments of the present invention, the slave block address SPRA0 and the upper predecoding addresses PRA1˜PRA(n−1), which may be generated in the master address generation unit 310, may form the slave address SADD. The slave address generation unit 320 may generate the slave block address SPRA0 in response to the buffered input address IADD(A0) (e.g., row address RA0) output from the row address buffer 311.

The slave address generation unit 320 may include a slave address converter 321 and a slave predecoder 323. The slave address converter 321 may convert a lowest row address RA0 into a slave row address SRA0. For example, the slave row address SRA0 may be based on the value of N, for example, SRA0 may be ‘RA0+N’ (N=1, 2, . . . ). As discussed above, the memory bank identified by the slave address SADD may differ from the memory bank identified by the master address MADD. In example embodiments of the present invention, both the master address MADD and the slave address SADD may be based upon the input address IADD.

The slave address SADD composed of the slave block address SPRA0 and the upper predecoding addresses PRA1˜PRA(n−1) may be provided to the row decoder 400.

Referring again to FIG. 1, the row decoder 400 may decode the master address MADD and the slave address SADD, and may select wordlines WLi and WLj, for example, based on the decoded master address MADD and slave address SADD. The wordline WLi corresponding to the master address MADD may be activated (e.g., constantly activated), for example, regardless (e.g., independently) of the logic state (e.g., logic High, ‘H’, Low, ‘L’, ‘1’, ‘0’, etc.) of the slave control signal SCON. The activation of the wordline WLj may be dependent on the logic state (e.g., logic High, ‘H’, Low, ‘L’, ‘1’, ‘0’, etc.) of the slave control signal SCON. A semiconductor memory device, according to example embodiments of the present invention, may include a memory, which may have a page size that may vary with the generation of the slave command SCMD.

For example, when the slave command SCMD is generated, the wordline WLi and the wordline WLj may be activated, and if 1K memory cells are connected to the same wordline, the semiconductor memory device, according to example embodiments of the present invention, may have a 2K memory size (e.g., a 2K page size).

If the slave command SCMD is not generated, the wordline WLi corresponding to the master address MADD may be activated, the wordline WLj corresponding to the slave address SADD may not be activated, and the semiconductor memory device, according to example embodiments of the present invention, may have a 1K memory size (e.g., a 1K page size).

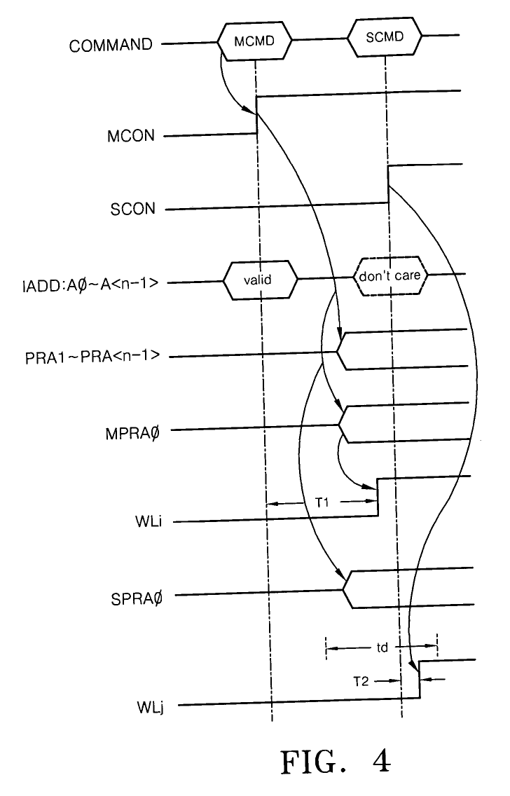

FIG. 4 is a timing diagram for the semiconductor memory device, according to example embodiments of the present invention. Referring to FIG. 4, the operation of the semiconductor memory device (e.g., as illustrated in FIG. 1), according to example embodiments of the present invention, is described below.

For example, the master command MCMD and the input address (e.g., valid input address) IADD may be received, and in response, the master control signal MCON may be generated.

In response to the master control signal MCON, the master address MADD (e.g., MPRA0, PRA1˜PRA(n−1)) may be generated, the slave address SADD (e.g., SPRA0, PRA1˜PRA(n−1)) may be generated, and the wordline WLi (e.g., corresponding to the master address MADD) may be activated.

When the slave command SCMD is generated, the slave control signal SCON may be activated. In response to the control signal SCON, the wordline WLj (e.g., corresponding to the slave address SADD) may be activated.

In example embodiments of the present invention, if the wordline WLj is activated in response to the slave control signal (e.g., as discussed above), a time T2 (e.g., representing a time interval from the generation of the slave command SCMD to the activation of the wordline WLj), may be less, or substantially less, than a time T1 (e.g., representing a time interval from the generation of the master command MCMD to the activation of the wordline WLi), for example, because the slave address SADD may have been previously generated in response to the master command MCMD.

In this case, since the time T2 may be less, or substantially less, than the time T1, the time taken to activate the wordlines WLi and WLj (e.g., in order to operate at a page size of 2K) may be similar, or substantially similar, to the time required for activating multiple wordlines in a related art semiconductor memory device.

However, in a semiconductor memory device, according to example embodiments of the present invention, since activation of the wordline WLj occurs a time T3 after the activation of the wordline WLi, the active peak current (e.g., as a result of operating at a page size of 2K) may decrease. Time T3 may be a time interval beginning after the activation of the wordline WLi, and may be any suitable length of time.

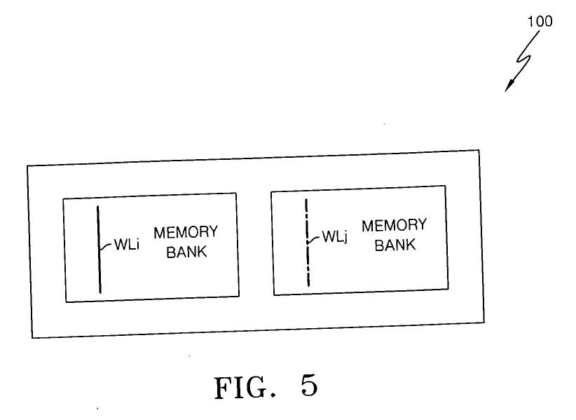

FIG. 5 is a diagram illustrating a memory bank in which at least one wordline may be activated, according to an example embodiment of the present invention. FIG. 5 may illustrate an example in which the memory cell array 100 may include, a plurality of memory banks (e.g., two memory banks). The memory cell array 100 may include any suitable number of memory banks.

Referring to FIG. 5, similar to that as discussed above, the memory bank identified by the master address MADD may be different from the memory bank identified by the slave address SADD.

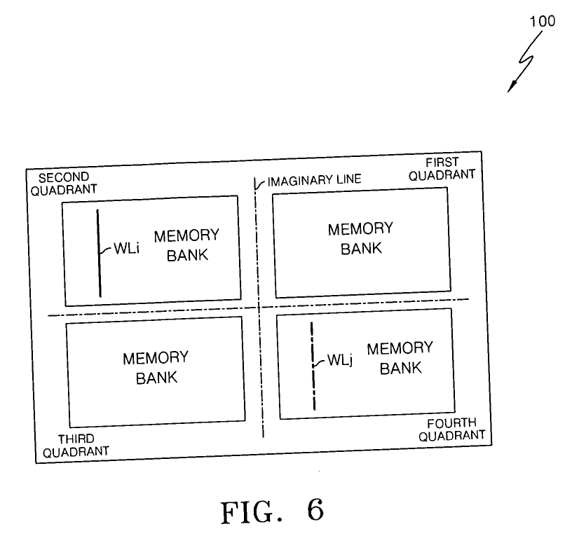

FIG. 6 is a diagram showing memory banks in which multiple wordlines may be activated (e.g., effectively activated), for example, when the memory cell array 100 includes four memory banks. Referring to FIG. 6, the memory bank identified by the master address MADD and the memory bank identified by the slave address SADD may be located, for example, diagonally with respect to one other.

In the example embodiment of the present invention, as illustrated in FIG. 6, the four memory banks may be arranged in first to fourth quadrants with respect to imaginary center lines. If the wordline WLi, activated by the master address MADD, is included in the memory bank of the second quadrant, the wordline WLj activated by the slave address SADD may be included in the memory bank of the fourth quadrant diagonal to the second quadrant.

In example embodiments of the present invention, the activated wordlines WLi and WLj may be located diagonally with respect to each other, and the current flowing through the semiconductor memory device may be more uniformly distributed (e.g., more relatively uniformly distributed).

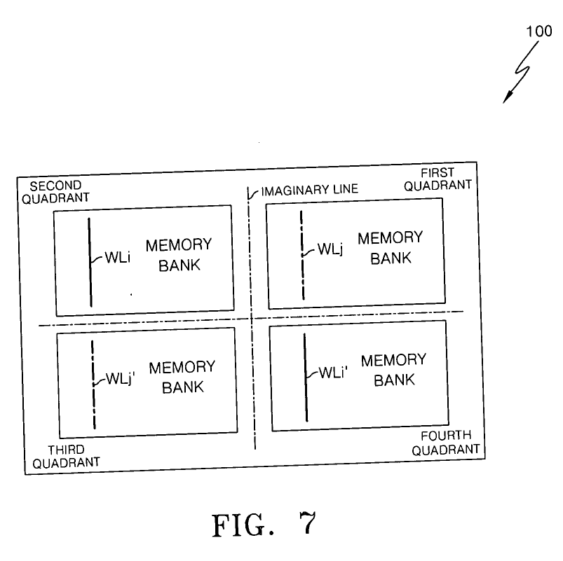

FIG. 7 is another diagram showing memory banks in which multiple wordlines may be activated (e.g., effectively activated), for example, in the memory cell array 100, which may include four memory banks. Referring to FIG. 7, the wordlines WLi and WLi′ of two memory banks, which may be located, for example, diagonally with respect to each other, may be identified by the master address MADD. The wordlines WLj and WLj′ of the other two memory banks may be identified by the slave address SADD.

In example embodiments of the present invention, each of the activated wordlines WLi, WLj, WLi′ and WLj′ may be located in one of the four quadrants, and the current flowing through the semiconductor device may be more uniformly distributed (e.g., more relatively uniformly distributed).

In semiconductor memory devices and methods of operating the same, according to example embodiments of the present invention, a memory size (e.g., a page size) may be controlled based on the generation of the slave command SCMD. In semiconductor memory devices and the methods of operating the same, according to example embodiments of the present invention, power consumption caused by, for example, variation in page size may be reduced, operational speed may be increased, and/or an active peak current may be reduced.

Example embodiments of the present invention have been described with respect a page size of 1K and/or 2K. However, it will be understood that example embodiments of the present invention may be utilized in conjunction with any suitable memory page size may be used (e.g., 8K, 16K, etc.).

Although example embodiments of the present invention have been described with reference to the example embodiments illustrated in the drawings, the example embodiments are illustrative. Those skilled in the art will appreciate that various modifications and equivalents are possible without departing from the scope and spirit of the invention as disclosed in the accompanying claims. Accordingly, the scope of the protection should be determined by the attached claims.

What is claimed is:

1. A semiconductor memory device, comprising:
a plurality of independently operated memory banks each of which includes a plurality of wordlines at least one of which is activated in response to a slave command and at least one of which is activated in response to a master command, wherein the slave command is independent of the master command.

2. The semiconductor memory device of claim 1, further including,
a row decoder adapted to activate at least one wordline based on a slave control signal generated in response to the slave command.

3. The semiconductor memory device of claim 2, further including,
an address control circuit adapted to generate a master address and a slave address based on an input address and output the master address and the slave address to the row decoder, and wherein
the row decoder activates at least two wordlines based on the master address and the slave address, respectively.

4. The semiconductor memory device of claim 3, wherein the master address and the slave address are linked to each other and each identify at least one wordline of different memory banks.

5. The semiconductor memory device as set forth in claim 3, wherein the at least one wordline identified by the slave address is activated after the at least one wordline identified by the master address.

6. The semiconductor memory device as set forth in claim 3, wherein the address control circuit further includes,
a master address generation unit adapted to generate the master address in response to the input address and output the generated master address to the row decoder; and
a slave address generation unit adapted to generate the slave address in response to the input address.

7. The semiconductor memory device as set forth in claim 3, wherein the semiconductor memory device includes four memory banks located in first to fourth quadrants, and
the memory bank identified by the master address and the memory bank identified by the slave address are located diagonally with respect to each other.

8. The semiconductor memory device as set forth in claim 3, wherein the semiconductor memory device includes four memory banks located in first to fourth quadrants, and wherein
the master address identifies wordlines of two memory banks located diagonally with respect to each other, and
the slave address identifies wordlines of two memory banks located diagonally with respect to each other.

9. A method of operating a semiconductor memory device, the method comprising:
receiving a master command and an input address;
generating a master address and a slave address corresponding to the input address and in response to the master command;
activating a wordline identified by the master address; and
activating a wordline identified by the slave address in response to generation of the master command and a slave command, wherein the slave command is independent of the master command.

10. The method of claim 9, wherein the master address and the slave address are linked to each other and identify the wordlines of different memory banks.

11. The method of claim 10, wherein the wordline identified by the slave address is activated after the activation of the wordline identified by the master address.

12. A semiconductor memory device comprising:
a memory having a variable page size determined based on a master command signal and a slave command signal, which are independent of each other.

13. The semiconductor device of claim 13, wherein memory further includes a plurality of independently operated memory banks, and the page size is further determined based on the plurality of independently operated memory banks each of which includes a plurality of wordlines at least one of which is activated in response to the slave command.

14. A method for operating a semiconductor memory device, the method comprising:
determining a page size of a memory within the semiconductor memory device based on a master command signal and a slave command signal, which are independent of each other.

15. The method of claim 15, where in the determining of the page size is further based on a plurality of independently operated memory banks, within the memory, each of which includes a plurality of wordlines at least one of which is activated in response to the slave command.
